(19) United States
(12) Patent Application Publication
(10) Pub. No.: US 2022/0142009 A1
(43) Pub. Date: May 5, 2022

(54) WATER-COOLER HEAT DISSIPATION DEVICE AND ELECTRICAL DEVICE

(71) Applicant: Sungrow Power Supply Co., Ltd., Hefei (CN)

(72) Inventors: Xuan Li, Hefei (CN); Jie Zhou, Hefei (CN)

(73) Assignee: Sungrow Power Supply Co., Ltd., Hefei (CN)

(21) Appl. No.: 17/408,286

(22) Filed: Aug. 20, 2021

(30) Foreign Application Priority Data
Nov. 2, 2020 (CN) 202011204606.9

(51) Int. Cl. H05K 7/20; F28F 3/04

(52) U.S. Cl. CPC H05K 7/20872; H05K 7/20854; F28F 2240/00; F28F 2230/00; F28F 3/048

(57) ABSTRACT

A water-cooled heat dissipation device and an electrical device are provided. The water-cooled heat dissipation device includes a first water-cooled plate and a sealing plate. The first water-cooled plate includes a first water-cooled substrate and multiple first heat dissipation fins arranged on the first water-cooled substrate. The sealing plate includes a sealing plate substrate and multiple second heat dissipation fins arranged on the sealing plate substrate and each arranged between two first heat dissipation fins, and the water-cooled substrate is hermetically matched with the sealing plate substrate to form a water-cooled cavity for accommodating the first heat dissipation fins and the second heat dissipation fins. In the water-cooled heat dissipation device according to the present application, the second heat dissipation fins are provided on the sealing plate substrate, so as to increase the overall heat dissipation area of the water-cooled heat dissipation device.

The present application claims the priority to Chinese patent application No. 202011204606.9 titled “WATER-COOLER HEAT DISSIPATION DEVICE AND ELECTRICAL DEVICE”, filed with the China National Intellectual Property Administration on Nov. 2, 2020, which is incorporated herein by reference in its entirety.

### FIELD

The present application relates to the technical field of heat dissipation of electrical devices, and in particular to a water-cooler heat dissipation device. Another object of the present application is to provide an electrical device including the above water-cooler heat dissipation device.

### BACKGROUND

For heat dissipation mounted with a heating device, natural cooling and air cooling are generally used to dissipate heat. However, for an electrical device with high heat flux density, air cooling can no longer meet the heat dissipation requirement, and a liquid cooling method with a relatively great heat exchange capacity is required for heat dissipation.

For example, the liquid cooling method is used by an electric vehicle controller, and a water-cooled plate of the electric vehicle controller is generally designed with different sizes of fins in a cavity to form different water passages, so that an area of a tooth is as large as possible and a heat dissipation area of the water-cooled plate is increased. A conventional water-cooled heat dissipation device is formed by die-casting. However, due to the limitation of the die-casting molding process, the heat dissipation fins cannot be thinned and the tooth spacing is reduced, which also limits the heat dissipation area of the tooth, and results in poor heat dissipation efficiency of the water-cooled heat dissipation device.

Therefore, those skilled in the art have a strong desire is how to improve the heat dissipation efficiency of the water-cooled heat dissipation device.

### SUMMARY

An object according to the present application is to provide a water-cooled heat dissipation device, so as to improve the heat dissipation efficiency of the water-cooled heat dissipation device. Another object according to the present application is to provide an electrical device including the above water-cooled heat dissipation device.

In order to achieve the above objects, a water-cooled heat dissipation device is provided according to the present application, which includes a first water-cooled plate and a sealing plate. The first water-cooled plate includes a first water-cooled substrate and multiple first heat dissipation fins arranged on the first water-cooled substrate. The sealing plate includes a sealing plate substrate and multiple second heat dissipation fins arranged on the sealing plate substrate and each arranged between two first heat dissipation fins, and the first water-cooled substrate is hermetically matched with the sealing plate substrate to form a water-cooled cavity for accommodating the multiple first heat dissipation fins and the multiple second heat dissipation fins.

Preferably, the water-cooled heat dissipation device includes a first heat-conducting component with one end connected to the first water-cooled substrate and the other end connected to the second heat dissipation fins.

Preferably, the first heat-conducting component includes a first elastic compression member, a first end of the first elastic compression member is connected to the first water-cooled substrate, and a second end of the first elastic compression member is connected to free ends of the second heat dissipation fins.

Preferably, the first heat-conducting component includes a first heat-conducting plate connected at the second end of the first elastic compression member, and the first elastic compression member abuts against the second heat dissipation fins through the first heat-conducting plate.

Preferably, the first elastic compression member is a spring, and the second end of the first elastic compression member is a heat-conducting plane which abuts against the first heat dissipation fins.

Preferably, multiple first elastic compression members are arranged between two adjacent first heat dissipation fins.

Preferably, the first heat-conducting component is first heat-conducting glue filled at a groove bottom of the two adjacent first heat dissipation fins.

Preferably, the sealing plate is a second water-cooled plate, and the water-cooled heat dissipation device further includes a second heat-conducting component with one end connected to the first heat dissipation fins and the other end connected to the sealing plate substrate.

Preferably, the second heat-conducting component includes a second elastic compression member, a first end of the second elastic compression member is connected to the sealing plate substrate, and a second end of the second elastic compression member is connected to free ends of the first heat dissipation fins.

Preferably, the second heat-conducting component includes a second heat-conducting plate connected at the second end of the second elastic compression member, and the second elastic compression member abuts against the first heat dissipation fins through the second heat-conducting plate.

Preferably, the second elastic compression member is a spring, and the second end of the second elastic compression member is a heat-conducting plane which abuts against the first heat dissipation fins.

Preferably, multiple second elastic compression members are arranged between two adjacent second heat dissipation fins.

Preferably, the second heat-conducting component is second heat-conducting glue filled at a groove bottom of the two adjacent second heat dissipation fins.

Preferably, spacing between the two adjacent first heat dissipation fins is equal to spacing between the two adjacent second heat dissipation fins.

Preferably, the multiple first heat dissipation fins and the multiple second heat dissipation fins are arranged alternately in sequence.

Preferably, the first water-cooled plate and/or the sealing plate have/has an integrally formed structure.

Preferably, the first water-cooled plate and/or the sealing plate have/has a die-casting structure.

An electrical device includes a water-cooled heat dissipation device and a heat generating module arranged on the water-cooled heat dissipation device, and the water-cooled heat dissipation device is the water-cooled heat dissipation device according to any one of the above.

Preferably, the electrical device is an electric vehicle controller.

In the above technical solution, the water-cooled heat dissipation device according to the present application includes the first water-cooled plate and the sealing plate. The first water-cooled plate includes a first water-cooled substrate and the first heat dissipation fins arranged on the first water-cooled substrate. The sealing plate includes the sealing plate substrate and the second heat dissipation fins arranged on the sealing plate substrate and each arranged between two first heat dissipation fins, and the first water-cooled substrate is hermetically matched with the sealing plate substrate to form the water-cooled cavity for accommodating the first heat dissipation fins and the second heat dissipation fins.

As can be seen from the above description, in the water-cooled heat dissipation device according to the present application, the second heat dissipation fins are provided on the sealing plate substrate, so as to increases the overall heat dissipation area of the water-cooled heat dissipation device, thereby improving the heat dissipation efficiency of the water-cooled heat dissipation device.

### BRIEF DESCRIPTION OF THE DRAWINGS

For more clearly illustrating embodiments of the present application or the technical solutions in the conventional technology, drawings to be used in the description of the embodiments or the conventional technology will be briefly described hereinafter. Apparently, the drawings in the following description are only some embodiments of the present application. For those skilled in the art, other drawings may be obtained based on the provided drawings without any creative work.

FIG. 1 is a three-dimensional structural sectional diagram of a water-cooled heat dissipation device according to an embodiment of the present application;

FIG. 2 is a three-dimensional structural diagram of an electrical device according to an embodiment of the present application;

FIG. 3 is a schematic structural diagram of a first water-cooled plate according to an embodiment of the present application;

FIG. 4 is a schematic structural diagram of a sealing plate according to an embodiment of the present application;

FIG. 5 is a partial schematic structural diagram of a first water-cooled heat dissipation device according to an embodiment of the present application;

FIG. 6 is a three-dimensional structural diagram of the first water-cooled heat dissipation device in FIG. 5;

Figure is a partial schematic structural diagram of a second water-cooled heat dissipation device according to an embodiment of the present application;

FIG. 8 is a partial schematic structural diagram of a third water-cooled heat dissipation device according to an embodiment of the present application;

FIG. 9 is a partial schematic structural diagram of a fourth water-cooled heat dissipation device according to an embodiment of the present application;

FIG. 10 is a partial schematic structural diagram of a fifth water-cooled heat dissipation device according to an embodiment of the present application.

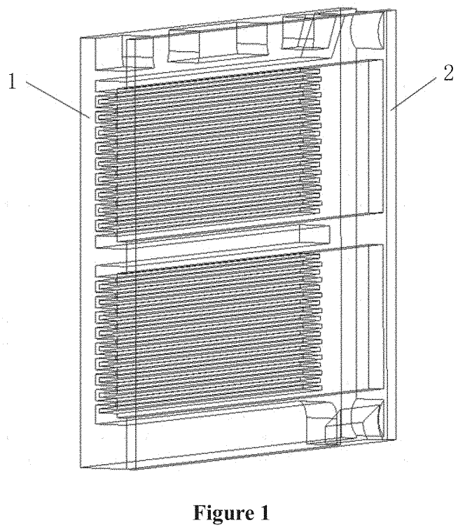

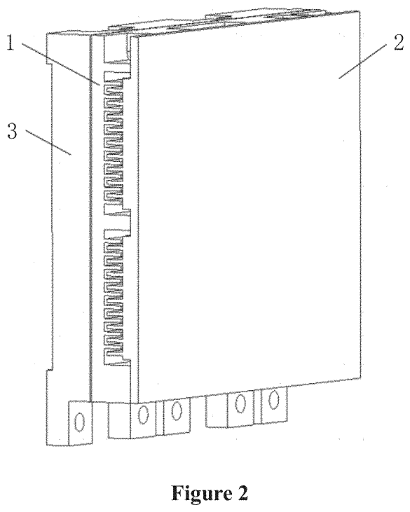

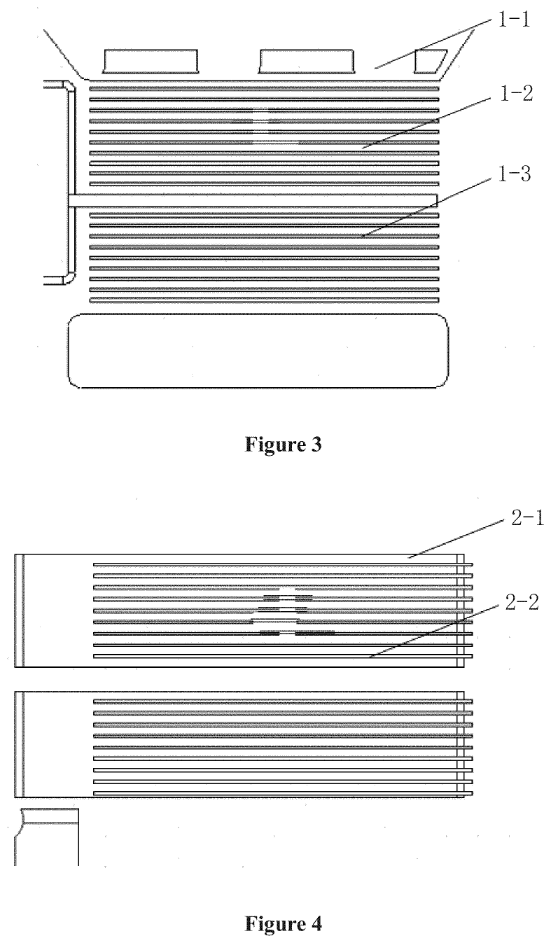

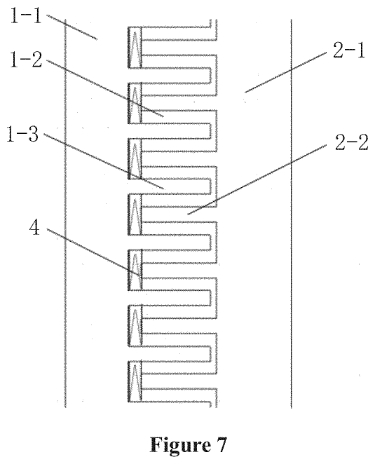

Reference numerals in FIGS. 1 to 10:

| | |
|---|---|
| 1 first water-cooled plate; | 1-1 first water-cooled substrate; |
| 1-2 water cooled cavity; | 1-3 first heat dissipation fin; |
| 2 sealing plate; | 2-1 sealing plate substrate; |
| 2-2 second heat dissipation fin; | 3 heat generation module; |
| 4 first elastic compression | 5 first heat-conducting glue; |
| member; | |
| 6 second heat-conducting glue; | 7 second elastic compression member. |

### DETAILED DESCRIPTION OF THE EMBODIMENTS

A core of the present application is to provide a water-cooled heat dissipation device, so as to improve the heat dissipation efficiency of the water-cooled heat dissipation device. Another object according to the present application is to provide an electrical device including the above water-cooled heat dissipation device.

In order to enable those skilled in the art to better understand the technical solutions of the present application, the present application will be further described in detail below with reference to the drawings and embodiments.

References are made to FIG. 1 to 10.

In a specific embodiment, the water-cooled heat dissipation device according to an embodiment of the present application includes a first water-cooled plate 1 and a sealing plate 2. Specifically, a water inlet and a water outlet may be arranged at corresponding positions of the first water-cooled plate 1 and the sealing plate 2 as required, which is not limited in this application.

The first water-cooled plate 1 includes a first water-cooled substrate 1-1 and multiple first heat dissipation fins 1-3 arranged on the first water-cooled substrate 1-1. Specifically, the first heat dissipation fins 1-3 may have a flat plate structure or a curved structure or the like. The first heat dissipation fins 1-3 may be mounted on the first water-cooled substrate 1-1 by gluing, welding or the like. Preferably, any two adjacent first heat dissipation fins 1-3 have a same spacing.

The sealing plate 2 includes a sealing plate substrate 2-1 and multiple second heat dissipation fins 2-2 arranged on the sealing plate substrate 2-1 and each arranged between two first heat dissipation fins 1-3, and one second heat dissipation fin 2-2 is provided between the two first heat dissipation fins 1-3. Specifically, the second heat dissipation fins 2-2 may have a flat plate structure or a curved structure or the like. The second heat dissipation fins 2-2 may be mounted on the first water-cooled substrate 1-1 by gluing, welding or the like. Preferably, any two adjacent second heat dissipation fins 2-2 have a same spacing.

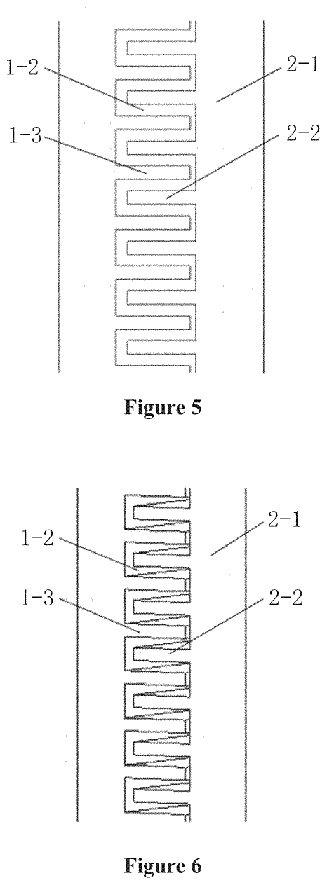

As shown in FIG. 5, preferably, the first heat dissipation fins 1-3 and the second heat dissipation fins 2-2 are arranged alternately in sequence. That is, one second heat dissipation fin 2-2 is provided between the two adjacent first heat dissipation fins 1-3.

In order to improve assembly efficiency, preferably, the first water-cooled plate 1 and/or the sealing plate 2 have/has an integrally formed structure. Specifically, the first water-cooled plate 1 and/or the sealing plate 2 have/has a die-casting structure. The first water-cooled plate 1 and the sealing plate 2 have a die-casting structure, which may both be an aluminum member.

Specifically, in order to improve the uniformity of heat dissipation, preferably, spacing between the two adjacent first heat dissipation fins 1-3 is equal to spacing between the two adjacent second heat dissipation fins 2-2.

The first water-cooled plate 1 and the sealing plate 2 are formed by die-casting, so that the problem of water-cooled heat dissipation with large loss is solved at low cost, which effectively enhances the heat dissipation capacity of the water-cooled system, reduces the cost, and has strong practicability.

The first water-cooled substrate 1-1 is hermetically matched with the sealing plate substrate 2-1 to form a water-cooled cavity 1-2 for accommodating the first heat dissipation fins 1-3 and the second heat dissipation fins 2-2. Specifically, the water-cooled cavity 1-2 may be provided in a groove structure on the first water-cooled substrate 1-1.

Specifically, a heat generation module 3 is attached to an outside of the first water-cooled substrate 1-1, and the heat of the heat generation module 3 is taken away by the water flowing in the water-cooled cavity 1-2. Specifically, the first heat dissipation fins 1-3 are formed by die-casting on the first water-cooled substrate 1-1, and the corresponding second heat dissipation fins 2-2 are formed by die-casting on the sealing plate 2, so that the first water-cooled plate 1 and the sealing plate 2 may be mounted in a staggered position together to form the water-cooled cavity 1-2. On this basis, a heat dissipation area of the fins may be doubled, thereby effectively improving the heat dissipation efficiency of the water-cooled heat dissipation device.

Due to the assembly and processing errors of the first water-cooled plate 1 and the sealing plate 2, the second heat dissipation fins 2-2 may not be possible to closely fit with the first water-cooled substrate 1-1. Preferably, the water-cooled heat dissipation device further includes a first heat-conducting component with one end connected to the first water-cooled substrate 1-1 and the other end connected to the second heat dissipation fins 2-2. In order to facilitate assembly and disassembly, preferably, one of the first water-cooled substrate 1-1 and the second heat dissipation fin 2-2 is fixedly connected to the first heat-conducting component, and the other one of the first water-cooled substrate 1-1 and the second heat dissipation fin 2-2 abuts against the first heat-conducting component. Specifically, the first heat-conducting component is made of material with relatively high thermal conductivity.

As shown in FIG. 7, the first heat-conducting component includes a first elastic compression member 4, a first end of the first elastic compression member 4 is connected to the first water-cooled substrate 1-1, and a second end of the first elastic compression member 4 is connected to free ends of the second heat dissipation fins 2-2.

Specifically, the first elastic compression member 4 may be a spring. In order to improve the thermal conduction efficiency, preferably, the second end of the first elastic compression member 4 is a heat-conducting plane which abuts against the second heat dissipation fins 2-2. That is, the spring type may be a flat spring so as to increase a contact area between the second heat dissipation fins 2-2 and the first water-cooled substrate 1-1.

Preferably, the first heat-conducting component includes a first heat-conducting plate connected at the second end of the first elastic compression member 4, and the first elastic compression member 4 abuts against the second heat dissipation fins 2-2 through the first heat-conducting plate. By providing the first heat-conducting plate, on one hand, the heat-conducting area is increased, and on the other hand, the first heat-conducting component is in stable contact with the second heat dissipation fin 2-2.

Specifically, the first elastic compression member 4 may be mounted by welding, gluing, crimping, interference fit, etc., and the spring material may be made of metal with a relatively high thermal conductivity, which is able to enhance the heat dissipation effect of the second heat dissipation fins 2-2.

In order to further improve the thermal conduction effect, preferably, multiple first elastic compression members 4 are arranged between the two adjacent first heat dissipation fins 1-3. Specifically, any two adjacent first elastic compression members 4 in the same row have a same spacing.

As shown in FIG. 8, in another embodiment, the first heat-conducting component is first heat-conducting glue 5 filled at a groove bottom of the two adjacent first heat dissipation fins 1-3. Specifically, the first heat-conducting glue 5 is heat-conducting glue with a relatively high thermal conductivity. Specifically, the second heat dissipation fin 2-2 may be connected to the first water-cooled substrate 1-1 through the first heat-conducting glue 5.

In a case that the heat generation modules 3 are mounted on two sides of the water-cooled heat dissipation device, preferably, the sealing plate 2 is used as a second water-cooled plate, the sealing plate substrate 2-1 is used as a second water-cooled substrate, and the water-cooled heat dissipation device further includes a second heat-conducting component with one end connected to the first heat dissipation fin 1-3 and the other end connected to the sealing plate substrate 2-1. By providing the second heat-conducting component, the heat of the heat generation module 3 on the second water-cooled plate may be taken out as soon as possible.

In order to facilitate assembly and disassembly, preferably, one of the sealing plate substrate 2-1 and the first heat dissipation fin 1-3 is fixedly connected to the second heat-conducting component, and the other one of the sealing plate substrate 2-1 and the first heat dissipation fin 1-3 abuts against the second heat-conducting component. Specifically, the second heat-conducting component is made of material with relatively high thermal conductivity.

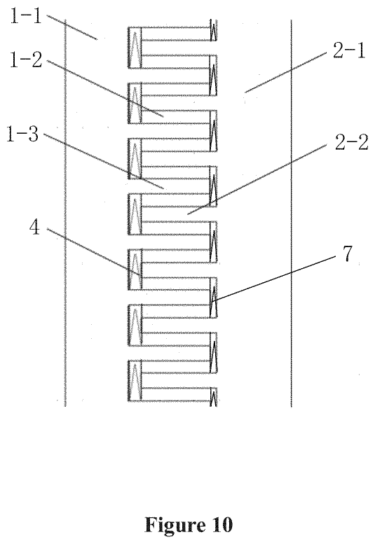

As shown in FIG. 10, specifically, the second heat-conducting component includes a second elastic compression member 7, a first end of the second elastic compression member 7 is connected to the sealing plate substrate 2-1, and a second end of the second elastic compression member 7 is connected to free ends of the first heat dissipation fins 1-3.

Specifically, the second elastic compression member 7 may be a spring. In order to improve the thermal conduction efficiency, preferably, the second end of the second elastic compression member 7 is a heat-conducting plane which abuts against the first heat dissipation fins 1-3. That is, the spring type may be a flat spring so as to increase a contact area between the first heat dissipation fins 1-3 and the sealing plate substrate 2-1.

Specifically, the second elastic compression member 7 may be mounted by welding, gluing, crimping, interference fit, etc., and the spring material may be made of metal with a relatively high thermal conductivity, which is able to enhance the heat dissipation effect of the first heat dissipation fins 1-3.

In an embodiment, the second heat-conducting component includes a second heat-conducting plate connected at the second end of the second elastic compression member 7, and the second elastic compression member 7 abuts against the first heat dissipation fin 1-3 through the second heat-conducting plate. By providing the second heat-conducting plate, on one hand, the heat-conducting area is increased, and on the other hand, the second heat-conducting component is in stable contact with the first heat dissipation fins 1-3.

In order to further improve the thermal conduction effect, preferably, multiple second elastic compression members 7 are arranged between the two adjacent second heat dissipation fins. Specifically, any two adjacent second elastic compression members 7 in the same row have a same spacing.

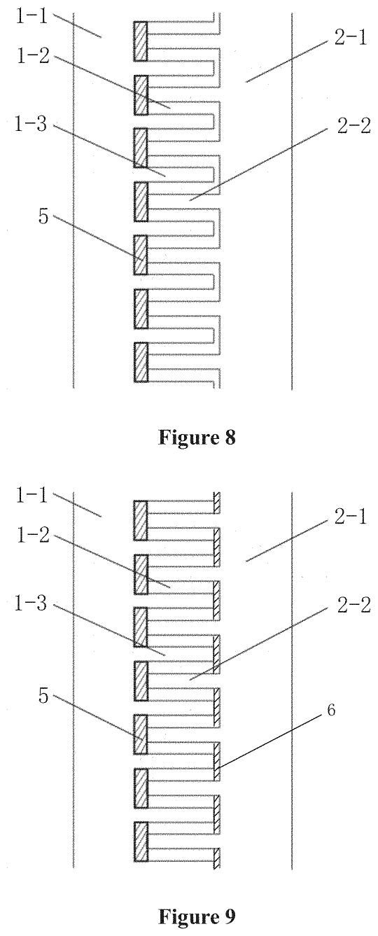

As shown in FIG. 9. In another embodiment, the second heat-conducting component is second heat-conducting glue 6 filled at a groove bottom of the two adjacent second heat dissipation fins 2-2. Specifically, the second heat-conducting glue 6 is heat-conducting glue with a relatively high thermal conductivity. Specifically, the first heat dissipation fins 1-3 may be connected to the sealing plate substrate 2-1 through the second heat-conducting glue 6.

An electrical device according to the present application includes a water-cooled heat dissipation device and a heat generation module 3 arranged on the water-cooled heat dissipation device, and the water-cooled heat dissipation device is the water-cooled heat dissipation device according to any one of the above. Specifically, the electrical device is an electric vehicle controller, or the electrical device may be other electrical device structures. The specific structure of the water-cooled heat dissipation device has been described above. And this application includes the above water-cooled heat dissipation device, which also has the above technical effects.

The above embodiments are described in a progressive manner. Each of the embodiments is mainly focused on describing its differences from other embodiments, and reference may be made among these embodiments with respect to the same or similar parts.

The above illustration of the disclosed embodiments can enable those skilled in the art to implement or use the present application. Various modifications to the embodiments are apparent to the person skilled in the art, and the general principle herein can be implemented in other embodiments without departing from the spirit or scope of the present application. Therefore, the present application is not limited to the embodiments described herein, but should be in accordance with the broadest scope consistent with the principle and novel features disclosed herein.

1. A water-cooled heat dissipation device, comprising a first water-cooled plate and a sealing plate; wherein
the first water-cooled plate comprises a first water-cooled substrate and a plurality of first heat dissipation fins arranged on the first water-cooled substrate; and
the sealing plate comprises a sealing plate substrate and a plurality of second heat dissipation fins arranged on the sealing plate substrate and each arranged between two of the plurality of first heat dissipation fins, and the first water-cooled substrate is hermetically matched with the sealing plate substrate to form a water-cooled cavity for accommodating the plurality of first heat dissipation fins and the plurality of second heat dissipation fins.

2. The water-cooled heat dissipation device according to claim 1, further comprising a first heat-conducting component with one end connected to the first water-cooled substrate and the other end connected to the second heat dissipation fins.

3. The water-cooled heat dissipation device according to claim 2, wherein the first heat-conducting component comprises a first elastic compression member, a first end of the first elastic compression member is connected to the first water-cooled substrate, and a second end of the first elastic compression member is connected to free ends of the second heat dissipation fins.

4. The water-cooled heat dissipation device according to claim 3, wherein the first heat-conducting component comprises a first heat-conducting plate connected at the second end of the first elastic compression member, and the first elastic compression member abuts against the second heat dissipation fins through the first heat-conducting plate.

5. The water-cooled heat dissipation device according to claim 3, wherein the first elastic compression member is a spring, and the second end of the first elastic compression member is a heat-conducting plane which abuts against the first heat dissipation fins.

6. The water-cooled heat dissipation device according to claim 3, wherein a plurality of first elastic compression members are arranged between two adjacent first heat dissipation fins.

7. The water-cooled heat dissipation device according to claim 2, wherein the first heat-conducting component is first heat-conducting glue filled at a groove bottom of the two adjacent first heat dissipation fins.

8. The water-cooled heat dissipation device according to claim 2, wherein the sealing plate is a second water-cooled plate, and the water-cooled heat dissipation device comprises a second heat-conducting component with one end connected to the first heat dissipation fins and the other end connected with the sealing plate substrate.

9. The water-cooled heat dissipation device according to claim 8, wherein the second heat-conducting component comprises a second elastic compression member, a first end of the second elastic compression member is connected to the sealing plate substrate, and a second end of the second elastic compression member is connected to free ends of the first heat dissipation fins.

10. The water-cooled heat dissipation device according to claim 9, wherein the second heat-conducting component comprises a second heat-conducting plate connected at the second end of the second elastic compression member, and the second elastic compression member abuts against the first heat dissipation fins through the second heat-conducting plate.

11. The water-cooled heat dissipation device according to claim 10, wherein the second elastic compression member is a spring, and the second end of the second elastic compression member is a heat-conducting plane which abuts against the first heat dissipation fins.

12. The water-cooled heat dissipation device according to claim 9, wherein a plurality of second elastic compression members are arranged between two adjacent second heat dissipation fins.

13. The water-cooled heat dissipation device according to claim 8, wherein the second heat-conducting component is second heat-conducting glue filled at a groove bottom of the two adjacent second heat dissipation fins.

14. The water-cooled heat dissipation device according to claim 1, wherein spacing between the two adjacent first heat dissipation fins is equal to spacing between the two adjacent second heat dissipation fins.

15. The water-cooled heat dissipation device according to claim 1, wherein the plurality of first heat dissipation fins and the plurality of second heat dissipation fins are arranged alternately in sequence.

16. The water-cooled heat dissipation device according to claim 1, wherein the first water-cooled plate and/or the sealing plate have/has an integrally formed structure.

17. The water-cooled heat dissipation device according to claim 16, wherein the first water-cooled plate and/or the sealing plate have/has a die-casting structure.

18. An electrical device, comprising a water-cooled heat dissipation device and a heat generation module arranged on the water-cooled heat dissipation device, wherein the water-cooled heat dissipation device is the water-cooled heat dissipation device according to claim 1.

19. The electrical device according to claim 18, wherein the electrical device is an electric vehicle controller.
